(19) United States
(12) Patent Application Publication
(10) Pub. No.: US 2014/0287226 A1
(43) Pub. Date: Sep. 25, 2014

(54) INGOT, SILICON CARBIDE SUBSTRATE, AND METHOD FOR PRODUCING INGOT

(71) Applicant: SUMITOMO ELECTRIC INDUSTRIES, LTD., Osaka (JP)

(72) Inventors: Tsutomu HORI, Itami-shi (JP); Makoto SASAKI, Itami-shi (JP); Shunsaku UETA, Itami-shi (JP); Tomohiro KAWASE, Itami-shi (JP)

(73) Assignee: SUMITOMO ELECTRIC INDUSTRIES, LTD., Osaka (JP)

(21) Appl. No.: 14/173,068

(22) Filed: Feb. 5, 2014

(30) Foreign Application Priority Data
Mar. 22, 2013 (JP) 2013-060072

(51) Int. Cl. C30B 23/00; C30B 29/36

(52) U.S. Cl. CPC C30B 23/002; C30B 29/36
USPC 428/332; 117/84

(57) ABSTRACT

There is obtained an ingot in which generation of crack is suppressed. The ingot includes: a seed substrate formed of silicon carbide; and a silicon carbide layer grown on the seed substrate. The silicon carbide layer has a thickness of 15 mm or more in a growth direction. When measuring a lattice constant in the silicon carbide layer at a plurality of measurement points in the growth direction, a difference between a maximum value of the lattice constant and a minimum value of the lattice constant is 0.004 nm or less. A distance between adjacent two points of the measurement points is 5 mm.

### BACKGROUND OF THE INVENTION

1. Field of the Invention

The present invention relates to an ingot, a silicon carbide substrate, and a method for producing the ingot, more particularly, an ingot formed of silicon carbide, an silicon carbide substrate obtained from the ingot, and a method for producing the ingot formed of silicon carbide.

2. Description of the Background Art

In recent years, in order to achieve high breakdown voltage, low loss, and the like in a semiconductor device, silicon carbide has begun to be adopted as a material for the semiconductor device. Silicon carbide is a wide band gap semiconductor having a band gap larger than that of silicon, which has been conventionally widely used as a material for semiconductor devices. Hence, by adopting silicon carbide as a material for a semiconductor device, the semiconductor device can have a high breakdown voltage, reduced on-resistance, and the like.

A silicon carbide ingot is produced by, for example, growing a silicon carbide single crystal on a seed substrate using a sublimation-recrystallization method. In the grown crystal of this silicon carbide ingot, strain or the like is generated. This may lead to generation of crack in the ingot or a silicon carbide substrate obtained by cutting the ingot. To address this, by easing processing conditions for the substrate or increasing an amount of removal in the substrate, a flat substrate having no crack can be obtained from the ingot having strain, for example. However, in this case, such a substrate can be broken by slight impact. This results in decrease of yield, disadvantageously. To address such a problem, Japanese Patent Laying-Open No. 2012-250864 discloses to relax strain or stress in a crystal by reducing a concentration gradient of metal atoms in a growth direction of an ingot, for example.

In Japanese Patent Laying-Open No. 2012-250864 described above, the strain in the crystal can be relaxed to some extent, but Japanese Patent Laying-Open No. 2012-250864 does not provide sufficient knowledge regarding a cause of generation of the strain or stress in the crystal. Hence, it is difficult to sufficiently suppress generation of crack in the silicon carbide ingot and the silicon carbide substrate.

### SUMMARY OF THE INVENTION

The present invention has been made in view of the foregoing problem, and has an object to provide an ingot in which generation of crack is suppressed, a silicon carbide substrate obtained by cutting the ingot, and a method for producing the ingot by which the generation of crack can be suppressed.

An ingot according to the present invention includes: a seed substrate formed of silicon carbide; and a silicon carbide layer grown on the seed substrate. The silicon carbide layer has a thickness of 15 mm or more in a growth direction. When measuring a lattice constant in the silicon carbide layer at a plurality of measurement points in the growth direction, a difference between a maximum value of the lattice constant and a minimum value of the lattice constant is 0.004 nm or less. A distance between adjacent two points of the measurement points is 5 mm.

The present inventors have conducted a detailed analysis on a cause of generation of strain in a crystal when producing an ingot by growing a silicon carbide layer on a seed substrate using the sublimation-recrystallization method. As a result, the present inventors have obtained the following knowledge, and have arrived at the present invention.

Generally, the sublimation-recrystallization method is performed by placing a seed substrate and a source material, each of which is formed of silicon carbide, in a crucible, and sublimating the source material to grow a silicon carbide layer on the seed substrate. At an early stage of the crystal growth, heat in the silicon carbide layer is consumed by heat transfer from the crucible, so that the temperature of the silicon carbide layer is maintained to be low. In contrast, at a later stage of the crystal growth, the thickness of the silicon carbide layer becomes larger, so that heat in the silicon carbide layer at its growth surface (surface opposite to the seed substrate) side is less likely to be consumed by the heat transfer from the crucible, with the result that a region at the growth surface side is more likely to have a higher temperature than a region at the seed substrate side. This is because the thermal conductivity of silicon carbide is drastically decreased at a temperature of not less than 2000° C., which is a crystal growth temperature of silicon carbide, as indicated by temperature dependency of thermal conductivity of silicon carbide in FIG. 10 (The horizontal axis of FIG. 10 represents a temperature (K) and the vertical axis represents the thermal conductivity (W/cm·K) of silicon carbide). Thus, the temperature difference between the region at the growth surface side and the region at the seed substrate side in the silicon carbide layer causes variation in lattice constant in the growth direction. This leads to generation of strain or the like in the crystal. This is particularly noticeable when the silicon carbide layer has a large thickness.

To address this, in the ingot according to the present invention, the thickness of the silicon carbide layer in the growth direction is large, i.e., 15 mm or more. Moreover, when measuring the lattice constant in the silicon carbide layer at each of the above-described measurement points, the difference between the maximum value of the lattice constant and the minimum value of the lattice constant is 0.004 nm or less. In other words, in this ingot, the variation in lattice constant is reduced in the growth direction of the silicon carbide layer. Hence, according to the ingot in the present invention, there can be provided an ingot in which crack is suppressed from being generated due to strain in its crystal. It should be noted that in this ingot, the measurement points may include a point on a growth surface of the silicon carbide layer opposite to the seed substrate.

When viewed in the growth direction, the ingot may have a width of 100 mm or more. In this way, an ingot having a larger diameter can be obtained. By cutting such an ingot, a silicon carbide substrate having a larger diameter can be obtained.

The ingot may have a polytype of 4H type. Thus, the ingot may have a polytype of 4H type, which is a representative polytype of silicon carbide.

A silicon carbide substrate according to the present invention is obtained by cutting the above-described ingot of the present invention in which generation of crack is suppressed. Thus, according to the silicon carbide substrate in the present invention, there can be provided a high-quality silicon carbide substrate in which generation of crack is suppressed.

A method for producing an ingot in the present invention includes the steps of: preparing a seed substrate and a source material each formed of silicon carbide; and growing a silicon carbide layer on the seed substrate by sublimating the source material. In the step of growing the silicon carbide layer, during a period of time from start of the growth of the silicon carbide layer to completion of the growth of the silicon carbide layer, a difference between a maximum value of a temperature of a growth surface of the silicon carbide layer opposite to the seed substrate and a minimum value of the temperature of the growth surface is maintained to be 30° C. or less.

As described above, in the conventional production of the ingot using the sublimation-recrystallization method, the temperature of the growth surface becomes higher as the growth of the silicon carbide layer progresses. As a result, the variation in lattice constant becomes large in the silicon carbide layer in the growth direction. Accordingly, the produced ingot has strain in its crystal to facilitate generation of crack.

To address this, in the method for producing the ingot according to the present invention, the silicon carbide layer is grown with the temperature fluctuation in the growth surface being suppressed (with the difference between the maximum value and the minimum value being maintained to be 30° C. or less) as described above. This reduces the variation in lattice constant in the growth direction of the silicon carbide layer, thereby suppressing generation of strain resulting from the variation. Thus, according to the method for producing the ingot in the present invention, there can be produced an ingot in which generation of crack is suppressed.

As apparent from the description above, according to the ingot in the present invention, there can be provided an ingot in which generation of crack is suppressed. Further, according to the silicon carbide substrate in the present invention, there can be provided a high-quality silicon carbide substrate in which generation of crack is suppressed. Furthermore, according to the method for producing the ingot in the present invention, there can be produced an ingot in which generation of crack is suppressed.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic side view showing an ingot according to the present embodiment.

FIG. 2 is a schematic perspective view showing a silicon carbide substrate according to the present embodiment.

FIG. 3 is a schematic view showing a hexagonal lattice structure of silicon carbide.

FIG. 4 is a schematic side view for illustrating measurement of a lattice constant in the ingot according to the present embodiment.

FIG. 5 is a schematic side view for illustrating measurement of the lattice constant in the ingot according to the present embodiment.

FIG. 6 is a flowchart schematically showing a method for producing the ingot according to the present embodiment.

FIG. 7 is a schematic cross sectional view for illustrating the method for producing the ingot according to the present embodiment.

FIG. 8 is a schematic cross sectional view for illustrating the method for producing the ingot according to the present embodiment.

FIG. 9 is a schematic cross sectional view for illustrating a method for measuring temperature fluctuation in a growth surface in the method for producing the ingot according to the present embodiment.

FIG. 10 is a graph showing a change of thermal conductivity of silicon carbide with temperature change.

### DESCRIPTION OF THE PREFERRED EMBODIMENTS

The following describes an embodiment of the present invention with reference to figures. It should be noted that in the below-mentioned figures, the same or corresponding portions are given the same reference characters and are not described repeatedly. Further, in the present specification, an individual orientation is represented by [ ], a group orientation is represented by < >, and an individual plane is represented by ( ) and a group plane is represented by { }. In addition, a negative index is supposed to be crystallographically indicated by putting “-” (bar) above a numeral, but is indicated by putting the negative sign before the numeral in the present specification.

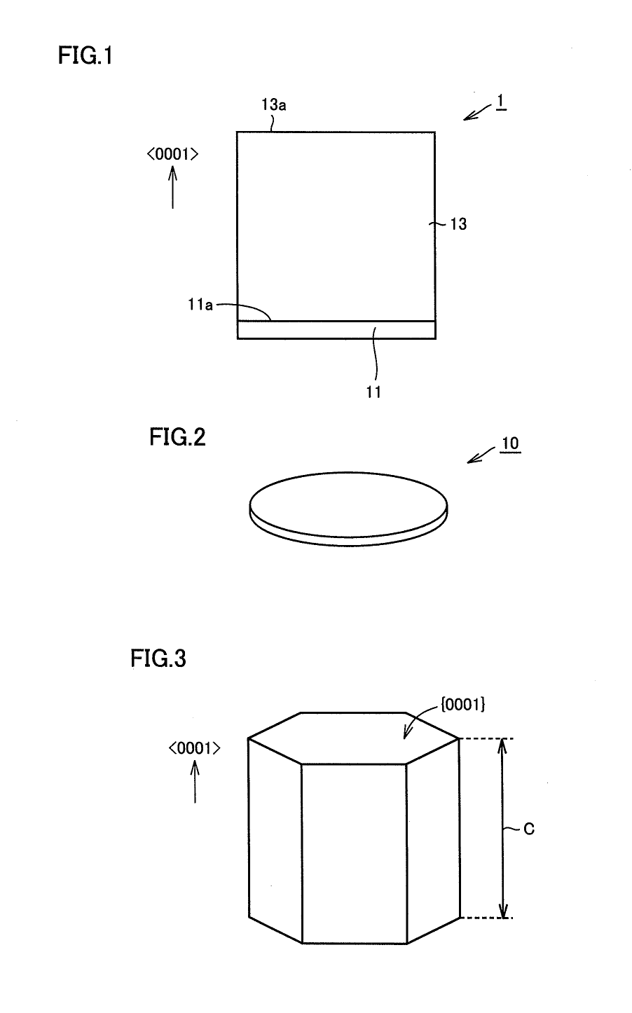

Described first are an ingot and a silicon carbide substrate in one embodiment of the present invention. Referring to FIG. 1, an ingot 1 according to the present embodiment is formed of silicon carbide having a polytype of 4H type, and includes a seed substrate 11 and a silicon carbide layer 13 grown on a surface 11a of seed substrate 11. Silicon carbide layer 13 is grown on seed substrate 11 in a <0001> direction (direction of arrow in FIG. 1) using the sublimation-recrystallization method. Hence, the growth direction of silicon carbide layer 13 corresponds to the <0001> direction. Referring to FIG. 2, a silicon carbide substrate 10 according to the present embodiment is obtained by cutting ingot 1 (see FIG. 1) in an appropriate direction.

Referring to FIG. 1, the thickness of silicon carbide layer 13 in the <0001> direction is 15 mm or more. The thickness thereof may be 15 mm, 20 mm, or 50 mm. The width (diameter) of ingot 1 when viewed in the <0001> direction is 100 mm or more. The width thereof may be 125 mm, 150 mm, or 175 mm.

When measuring a lattice constant in silicon carbide layer 13 at a plurality of measurement points in the <0001> direction, a difference between the maximum value of the lattice constant and the minimum value of the lattice constant is 0.004 nm or less, preferably 0.003 nm or less, more preferably 0.002 nm or less. A distance between adjacent two points of the measurement points is 5 mm. Thus, in silicon carbide layer 13, variation in lattice constant is reduced in the <0001> direction. Further, in silicon carbide layer 13, the lattice constant may be changed to be increased linearly or may be changed with a plurality of slopes in a direction from the seed substrate 11 side to the growth surface 13a side.

Referring to FIG. 3, the term “lattice constant” is intended to indicate a lattice constant C (nm) in the <0001> direction in a hexagonal lattice structure of silicon carbide. Lattice constant C can be measured through X-ray diffraction (XRD) using a Cu-Kα1 (wavelength: 0.15405 nm) as an X-ray source, for example. When performing the XRD measurement at the above-described measurement points in silicon carbide layer 13, a difference between the maximum value and minimum value of 2θ is 0.05° or less at a peak resulting from diffraction in a (0004) plane.

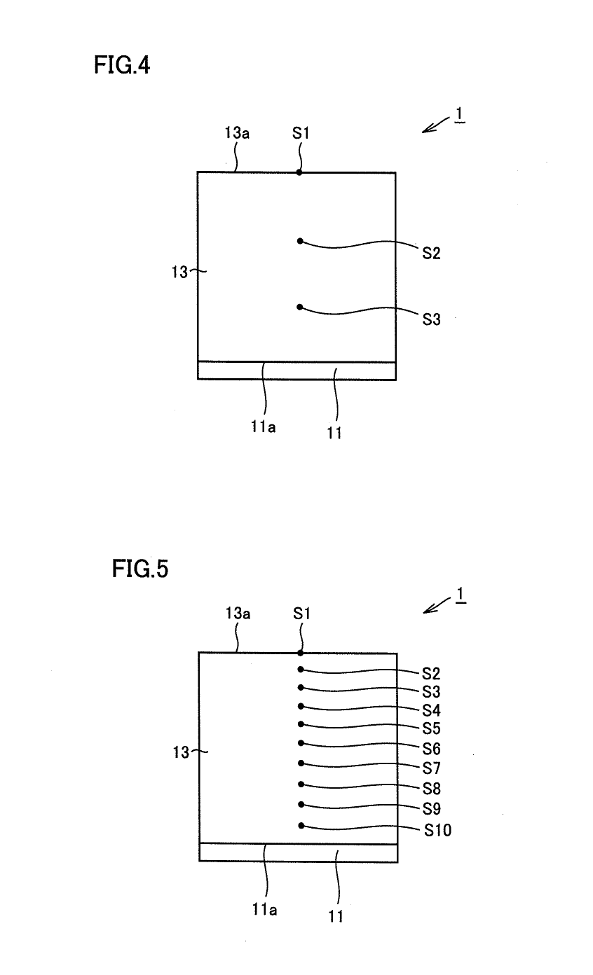

Referring to FIG. 4 and FIG. 5, the measurement points for measuring lattice constant C includes a measurement point S1 on growth surface 13a opposite to the seed substrate 11 side. Accordingly, when the thickness of silicon carbide layer 13 is, for example, 15 mm, the above-described measurement points includes: measurement point S1; a measurement point S2 away from measurement point S1 by a distance of 5 mm; and a measurement point S3 away from measurement point S2 by a distance of 5 mm (see FIG. 4). Likewise, when the thickness of silicon carbide layer 13 is, for example, 50 mm, the above-described measurement points include measurement points S1 to S10. Further, as shown in FIG. 4 and FIG. 5, the measurement points include a central portion of ingot 1 in the radial direction, and are not included in a region within 0.5 mm from surface 11a of seed substrate 11. The lattice constant at each of measurement points S1 to S10 can be measured by cutting ingot 1 to obtain a substrate, which includes measurement points S1 to S10, and performing the XRD measurement to this substrate.

As described above, in ingot 1 according to the present embodiment, the thickness of silicon carbide layer 13 in the <0001> direction is large, i.e., 15 mm or more. Moreover, when measuring the lattice constant in silicon carbide layer 13 at each of the above-described measurement points, the difference between the maximum value of the lattice constant and the minimum value of the lattice constant is reduced to 0.004 nm or less. Accordingly, in ingot 1, strain is suppressed from being generated in the crystal due to the variation in lattice constant. Thus, in ingot 1 according to the present embodiment, crack is suppressed from being generated.

Further, silicon carbide substrate 10 according to the present embodiment is obtained by cutting ingot 1 according to the present embodiment in which the crack is suppressed from being generated. Hence, the quality of this silicon carbide substrate 10 is high with the crack being suppressed from being generated.

The following describes a method for producing the ingot according to the present embodiment. In the method for producing the ingot according to the present embodiment, ingot 1 according to the present embodiment can be produced in which the generation of crack is suppressed.

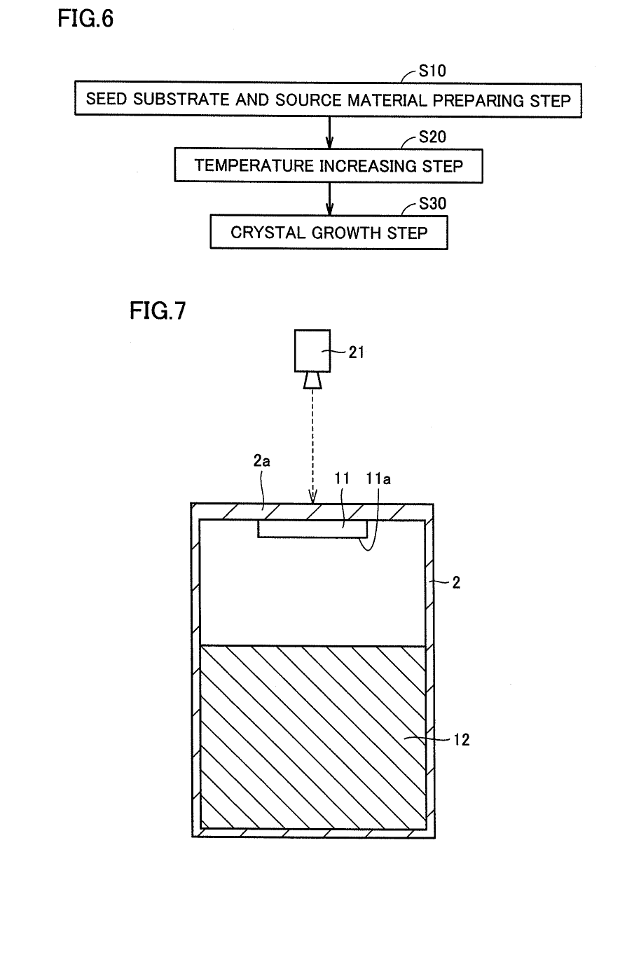

Referring to FIG. 6, a seed substrate and source material preparing step is first performed as a step (S10) in the method for producing the ingot according to the present embodiment. In this step (S10), referring to FIG. 7, seed substrate 11 formed of a silicon carbide single crystal and source material 12 formed of polycrystal silicon carbide powders or a silicon carbide sintered compact are prepared. Seed substrate 11 and source material 12 are placed face to face with each other in a crucible 2 formed of carbon as shown in FIG. 7.

Next, a temperature increasing step is performed as a step (S20). In this step (S20), referring to FIG. 7, while supplying argon (Ar) gas and nitrogen (N₂) gas into crucible 2, the temperature in crucible 2 is increased to a crystal growth temperature of silicon carbide using a heating coil (not shown) disposed external to crucible 2. In doing so, the inside of crucible 2 is heated such that the temperature is gradually decreased in a direction from the source material 12 side to the seed substrate 11 side (such that a temperature gradient is formed). Further, the temperature of an upper portion 2a of crucible 2, on which seed substrate 11 is placed, can be measured using a radiation thermometer 21 disposed external to (above) crucible 2.

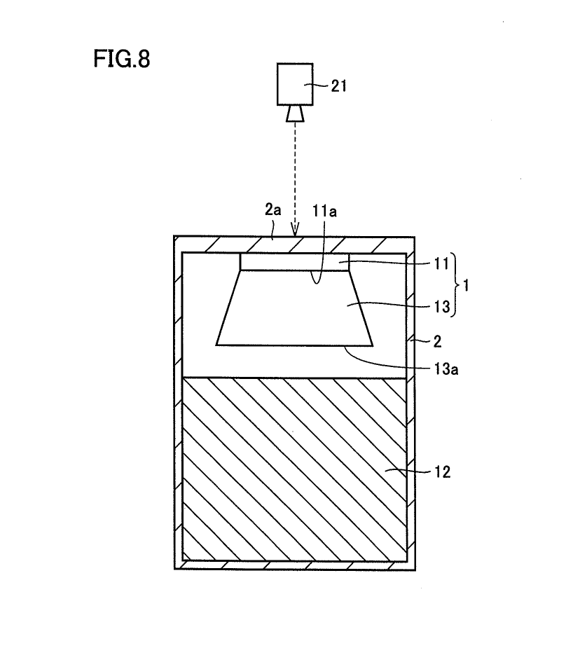

Next, as a step (S30), a crystal growth step is performed. In this step (S30), the inside of crucible 2 is heated to a predetermined temperature, and then pressure in crucible 2 is reduced to a predetermined pressure. In this way, source material 12 is sublimated to generate source material gas of silicon carbide, and the source material gas reaches surface 11a of seed substrate 11. As a result, as shown in FIG. 8, silicon carbide layer 13 grows on surface 11a of seed substrate 11. Then, after passage of a predetermined time, pressure is applied to the inside of crucible 2 to stop the growth of silicon carbide layer 13. Thereafter, crucible 2 is cooled. After completion of the cooling process, ingot 1 is taken out of crucible 2.

In this step (S30), during a period of time from the start of the growth of silicon carbide layer 13 to the completion of the growth, the current value of the heating coil (not shown) is adjusted such that a difference becomes 30° C. or less between the maximum value of the temperature of growth surface 13a of silicon carbide layer 13 opposite to seed substrate 11 and the minimum value of the temperature of growth surface 13a. More specifically, the current value of the heating coil is adjusted to be smaller as the temperature of growth surface 13a becomes gradually higher due to the growth of silicon carbide layer 13. Further, in this step (S30), the difference between the maximum value and the minimum value is preferably 20° C. or less, more preferably 15° C. or less, and further preferably 10° C. or less. Thus, in this step (S30), silicon carbide layer 13 is grown with the temperature fluctuation in growth surface 13a being suppressed.

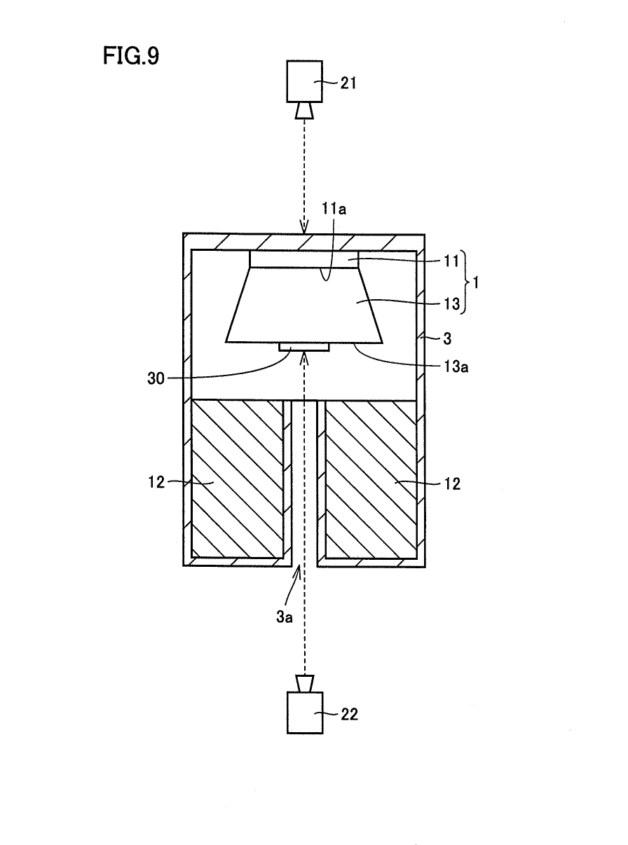

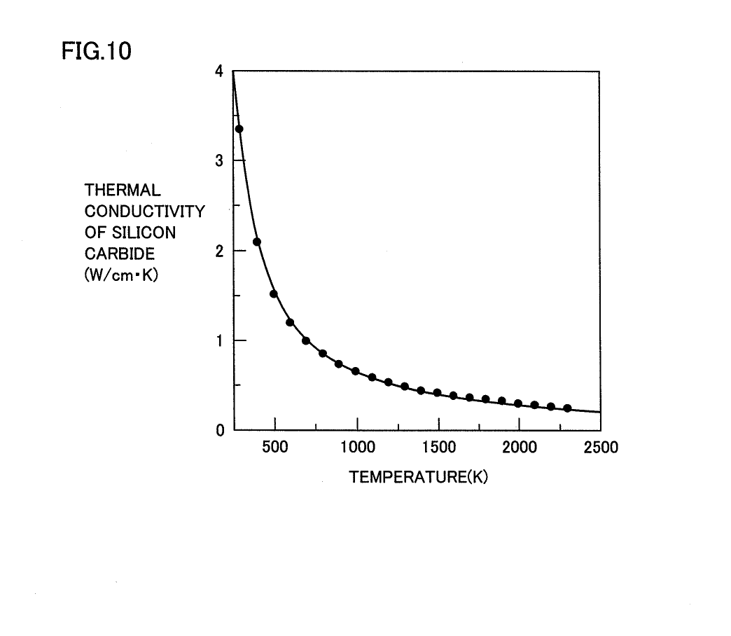

Further, in this step (S30), the temperature fluctuation in growth surface 13a can be suppressed in the following manner. Referring to FIG. 9, a crucible 3 having a hole portion 3a at its lower portion is first prepared. In crucible 3, source material 12 and seed substrate 11 are placed. Then, by sublimating source material 12, silicon carbide layer 13 is grown on seed substrate 11. At an appropriate time during the growth of silicon carbide layer 13, a carbon plate 30 is placed on growth surface 13a as shown in FIG. 9. Through carbon plate 30, the temperature of growth surface 13a is measured using a radiation thermometer 22. In this way, while checking the temperature of growth surface 13a during the growth of silicon carbide layer 13, the current value of the heating coil (not shown) is adjusted such that the temperature fluctuation in growth surface 13a becomes 30° C. or less. Thus, before performing step (S30), the heating condition can be set in advance to suppress the temperature fluctuation in growth surface 13a of silicon carbide layer 13.

In the manner described above, the above-described steps (S10) to (S30) are performed to produce ingot 1 according to the present embodiment (see FIG. 1), thus completing the method for producing the ingot according to the present embodiment. By cutting ingot 1 thus produced, silicon carbide substrate 10 according to the present embodiment can be obtained.

As described above, in the method for producing the ingot according to the present embodiment, silicon carbide layer 13 is grown with the temperature fluctuation in growth surface 13a being suppressed, thereby suppressing generation of strain in the crystal. Hence, according to the method for producing the ingot in the present embodiment, there can be produced ingot 1 in which generation of crack is suppressed.

### EXAMPLE

An experiment was conducted to confirm the effect of the present invention regarding the suppression of the generation of crack in the ingot or the silicon carbide substrate. Referring to FIG. 8, first, seed substrate 11 and source material 12 each formed of silicon carbide were prepared and were placed in crucible 2. Next, while supplying argon gas and nitrogen gas to crucible 2, the temperature in crucible 2 was increased. The flow rate of the argon gas was set at 100 ml/min, the flow rate of the nitrogen gas was set at 10 ml/min, and the pressure of the argon gas in crucible 2 was set at 70 kPa. Further, the temperature in crucible 2 was increased at a rate of 500 ° C./h.

The temperature of upper portion 2a of crucible 2 was increased from a normal temperature to 2200° C.

Next, after the temperature of upper portion 2a of crucible 2 reached 2200° C., the pressure in crucible 2 was reduced to 2 kPa to sublimate source material 12. Then, silicon carbide layer 13 was grown for 100 hours. In doing so, during the period of time from the start of the growth of silicon carbide layer 13 to the completion thereof, the current value of the heating coil (not shown) was adjusted such that the difference between the maximum value and the minimum value of the temperature in growth surface 13a became 30° C. or less. Next, after the completion of the growth of silicon carbide layer 13, the pressure in crucible 2 was increased to 70 kPa to stop the growth. Thereafter, crucible 2 was cooled at a rate of 100° C./h. After completion of the cooling process, ingot 1 was taken out. Ingot 1 had a thickness of 15 mm or 50 mm. Ingot 1 had a diameter of 100 mm, 125 mm, or 150 mm.

Next, in the case where the thickness of silicon carbide layer 13 was 15 mm, the lattice constant was measured at each of measurement points S1, S2, S3 shown in FIG. 4. In the case where the thickness of silicon carbide layer 13 was 50 mm, the lattice constant was measured at each of measurement points S1 to S10 shown in FIG. 5. Further, the value of the difference was calculated between the maximum value of the lattice constant and the minimum value of the lattice constant in each ingot. Then, existence/non-existence of crack was checked in each ingot. Results thereof are shown in Table 1. It should be noted that the existence/non-existence of the generated crack was checked by dropping an iron ball having a weight of 500 g onto a facet portion of the ingot from a height of 50 cm. When crack was generated, “Exist” is indicated in Table 1. When no crack was generated, “Not Exist” is indicated therein.

TABLE 1

| | | Difference between Maximum | Difference between Maximum | |
|---|---|---|---|---|
| Diameter | Thickness | Value and Minimum Value of | Value and Minimum Value of | |
| (mm) | (mm) | Temperature in Growth Surface (° C.) | Lattice Constant (nm) | Crack |
| 100 | 15 | 20 | 0.003 | Not Exist |
| 125 | 15 | 20 | 0.004 | Not Exist |
| 150 | 15 | 15 | 0.003 | Not Exist |
| 100 | 50 | 10 | 0.002 | Not Exist |
| 100 | 50 | 15 | 0.003 | Not Exist |
| 100 | 50 | 20 | 0.003 | Not Exist |
| 100 | 50 | 20 | 0.004 | Not Exist |
| 100 | 15 | 40 | 0.006 | Exist |
| 100 | 50 | 35 | 0.005 | Exist |

The following describes a result of the experiment. As shown in Table 1, when the difference between the maximum value and the minimum value of the temperature in the growth surface was 30° C. or less, the difference between the maximum value and the minimum value of the lattice constant in silicon carbide layer 13 became 0.004 nm or less. In this case, it was seen that no crack was generated.

In contrast, when the difference between the maximum value and the minimum value of the temperature in the growth surface was more than 30° C., the difference between the maximum value and the minimum value of the lattice constant became more than 0.004 nm. In this case, it was seen that crack was generated. From the result of this experiment, it was found that the variation in lattice constant can be made small in the silicon carbide layer by performing crystal growth while suppressing the temperature fluctuation in the growth surface, with the result that the generation of crack in the ingot can be suppressed.

The ingot, the silicon carbide substrate, and the method for producing the ingot according to the present invention can be particularly advantageously applied to an ingot, a silicon carbide substrate, and a method for producing the ingot, each of which is required to achieve suppression of generation of crack.

Although the present invention has been described and illustrated in detail, it is clearly understood that the same is by way of illustration and example only and is not to be taken by way of limitation, the scope of the present invention being interpreted by the terms of the appended claims.

What is claimed is:

1. An ingot comprising:
a seed substrate formed of silicon carbide; and
a silicon carbide layer grown on said seed substrate,
said silicon carbide layer having a thickness of 15 mm or more in a growth direction,
when measuring a lattice constant in said silicon carbide layer at a plurality of measurement points in said growth direction, a difference between a maximum value of said lattice constant and a minimum value of said lattice constant being 0.004 nm or less, a distance between adjacent two points of said measurement points being 5 mm.

2. The ingot according to claim 1, wherein
said measurement points include a point on a growth surface of said silicon carbide layer opposite to said seed substrate.

3. The ingot according to claim 1, wherein when viewed in said growth direction, the ingot has a width of 100 mm or more.

4. The ingot according to claim 1, wherein the ingot has a polytype of 4H type.

5. A silicon carbide substrate obtained by cutting the ingot of claim 1.

6. A method for producing an ingot comprising the steps of:
preparing a seed substrate and a source material each formed of silicon carbide; and
growing a silicon carbide layer on said seed substrate by sublimating said source material,
in the step of growing said silicon carbide layer, during a period of time from start of the growth of said silicon carbide layer to completion of the growth of said silicon carbide layer, a difference between a maximum value of a temperature of a growth surface of said silicon carbide layer opposite to said seed substrate and a minimum value of the temperature of said growth surface being maintained to be 30° C. or less.
